(19) United States
(12) Patent Application Publication
(10) Pub. No.: US 2026/0367682 A1
(43) Pub. Date: Nov. 19, 2026

(54) THREE-CHAMBER CHASSIS DEVICE

(71) Applicant: Corsair Memory, Inc., Milpitas, CA (US)

(72) Inventors: Joseph Eamonn L. Clerkin, Milpitas, CA (US); Mitch Podlaha, Milpitas, CA (US); Manny Melo, Milpitas, CA (US)

(21) Appl. No.: 19/676,108

(22) Filed: May 13, 2026

(30) Foreign Application Priority Data
May 15, 2025 (TW) 114204908

(51) Int. Cl. G06F 1/20; G06F 1/18; H05K 7/20

(52) U.S. Cl. CPC G06F 1/20; G06F 1/181; H05K 7/2039

(57) ABSTRACT

A three-chamber chassis device comprises a housing unit, a partition unit, and a chamber unit. The housing unit comprises a front panel, a rear panel, a left panel, a right panel, a bottom structure, and a top structure. The partition unit comprises a partition structure disposed within the housing unit, the partition structure being connected to the front panel, the rear panel, and the right panel, respectively, and extending longitudinally to the bottom structure and the top structure. The chamber unit is disposed within the housing unit and comprises a first chamber, a second chamber, and a third chamber, the partition structure isolating the first chamber, the second chamber, and the third chamber from one another to accommodate different computer components therein, respectively.

### CROSS-REFERENCE TO RELATED APPLICATIONS

This application claims the benefit of priority to Taiwanese patent application no. 114204908 filed May 15, 2025 entitled “Three-Chamber Chassis Device”, the contents of which are incorporated herein by reference in their entirety for all purposes.

### FIELD OF THE INVENTION

The present invention relates to a chassis device, and more particularly, to a three-chamber chassis device.

### BACKGROUND OF THE INVENTION

In many existing computer chassis designs, all major components—such as the central processing unit (CPU), graphics processing unit (GPU), and other computer hardware—are installed within a single shared space. As the performance of computer hardware increases, more heat is inevitably generated. This design approach may give rise to heat dissipation inefficiency.

Because these computer hardware components generate substantial heat during operation and are in close proximity to one another, heat may accumulate in the confined space, resulting in inadequate thermal management. This problem is particularly pronounced in high-performance computing or compute-intensive workloads. When heat cannot be dissipated in a timely manner, it may cause degradation in hardware performance and even shorten the service life of computer components.

Methods for improving computer heat dissipation include designing more efficient thermal systems, such as adding fans, upgrading liquid cooling systems, or improving the materials and design of heat sinks. In addition, some newer chassis designs have adopted zone-partitioned layouts that separate high-heat-generating components such as CPUs and GPUs to facilitate more effective heat routing and exhaust. A zone-partitioned structure can reduce inter-component thermal conduction while enhancing overall heat dissipation efficiency.

Referring to FIG. 1, U.S. Pat. No. 10,459,498 discloses a chassis 1 comprising a front panel 11, a rear panel 12, a bottom shell 13, a top structure 14, a first partition 15, and a second partition 16. The first partition 15 is connected to the front panel 11 and the rear panel 12 and extends vertically between the bottom shell 13 and the top structure 14. The second partition 16 is connected to the front panel 11 and the rear panel 12 and extends laterally from the first partition 15. Together, the first partition 15 and the second partition 16 divide the interior of the chassis 1 into a main space 17, a lower space 18, and an upper space 19.

Although a multi-space chassis 1 has been disclosed in the prior art, the following drawbacks remain in practical use:
(1) Inability to form a chimney-style heat dissipation structure:

In the known chassis 1, the second partition 16 is disposed horizontally to divide the interior into the upper space 19 and the lower space 18. Blocked by the second partition 16, the bottom of the upper space 19 is not ventilated, and the top of the lower space 18 likewise cannot be ventilated. Accordingly, both the upper space 19 and the lower space 18 must be ventilated from the sides, and a chimney-style heat dissipation structure cannot be formed.
(2) Inability to install a transparent side panel:

Today's mainstream side-panel-window chassis designs use full-panel transparent side panels to showcase the computer components installed inside. However, because the upper space 19 and the lower space 18 of the known chassis 1 must be ventilated from the sides, the side panels (not shown) must incorporate ventilation structures, precluding the use of transparent side panels. Accordingly, the known chassis 1 suffers from the drawback of being incompatible with transparent side panels.
(3) Relatively high structural height:

In the known chassis 1, the upper space 19 accommodates the motherboard and CPU, while the lower space 18 accommodates the power supply unit. The upper space 19 is stacked above the lower space 18, and both the motherboard and the power supply unit are oriented in an upright position, requiring the chassis 1 to have sufficient height to accommodate these computer components.

There is accordingly a need in the art for a multi-space chassis design that enables chimney-style heat dissipation, supports the installation of transparent side panels, and reduces the overall structural height of the chassis.

### SUMMARY OF THE INVENTION

Some embodiments of the present invention provide a three-chamber chassis device. The three-chamber chassis device comprises a housing unit, a partition unit, and a chamber unit.

The housing unit comprises a front panel, a rear panel, a left panel, a right panel, a bottom structure, and a top structure. The front panel, the rear panel, the left panel, and the right panel are sequentially connected and arranged around the bottom structure and the top structure.

The partition unit comprises a partition structure disposed within the housing unit. The partition structure is connected to the front panel, the rear panel, and the right panel, respectively, and extends longitudinally to the bottom structure and the top structure.

The chamber unit is disposed in the housing unit and comprises a first chamber, a second chamber, and a third chamber separated by the partition structure. The first chamber is defined by the partition structure, the front panel, the rear panel, the left panel, the bottom structure, and the top structure. The second chamber is defined by the partition structure, the front panel, the right panel, the bottom structure, and the top structure. The third chamber is defined by the partition structure, the rear panel, the right panel, the bottom structure, and the top structure.

The features of the present invention reside in that the partition structure extends longitudinally to the bottom structure, and the top structure to isolate the first chamber, the second chamber, and the third chamber. All three chambers are disposed at the same height, thereby enabling a reduction in the overall structural height of the housing unit. In addition, externally communicating ventilation structures may be provided on the bottom structure and the top structure so that the first chamber, the second chamber, and the third chamber each independently form a chimney-style heat dissipation structure. Furthermore, the front panel, the left panel, and the right panel may employ transparent panels to display the computer components installed within the housing unit to the outside.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a perspective view of the chassis of U.S. Pat. No. 10,459,498.

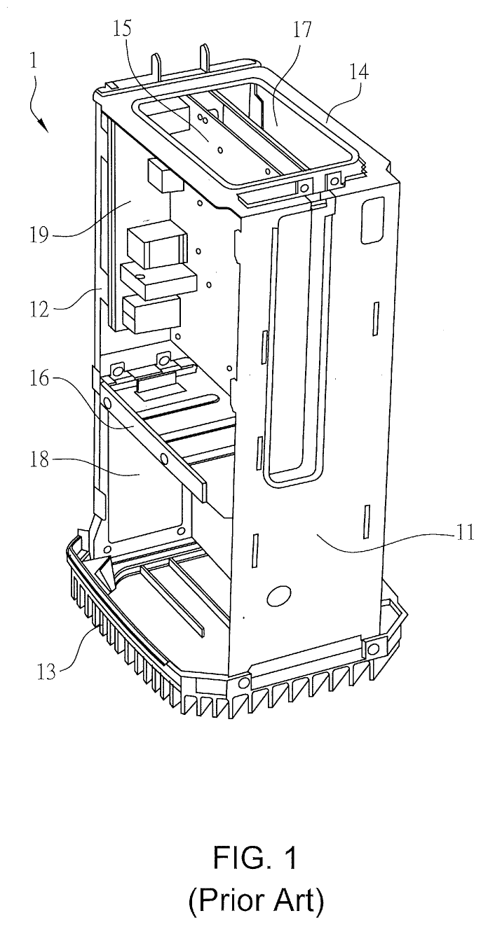

FIG. 2 is a perspective view of a three-chamber chassis device according to a first embodiment of the present invention.

FIG. 3 is another perspective view of the three-chamber chassis device according to the first embodiment.

FIG. 4 is a partial top view of the housing unit according to the first embodiment.

FIG. 5 is a side view of a three-chamber chassis device according to a second embodiment of the present invention.

FIG. 6 is a front view of a three-chamber chassis device according to a third embodiment of the present invention.

FIG. 7 is a top view of a three-chamber chassis device according to a fourth embodiment of the present invention.

FIG. 8 is a bottom view of the housing unit according to the fourth embodiment.

FIG. 9 is a perspective view of the three-chamber chassis device according to the fourth embodiment.

### DETAILED DESCRIPTION OF THE PREFERRED EMBODIMENTS

Hereinafter, the present embodiment will be described in detail with appropriate reference to the drawings. In the drawings used in the following description, there are cases where characteristic portions are enlarged for convenience to make it easier to understand features of the present invention, and dimensional ratios of each component may differ from the actual ones. Materials, dimensions, and the like exemplified in the following description are examples, and the present invention is not limited thereto and can be implemented with appropriate modifications within a scope of the present invention.

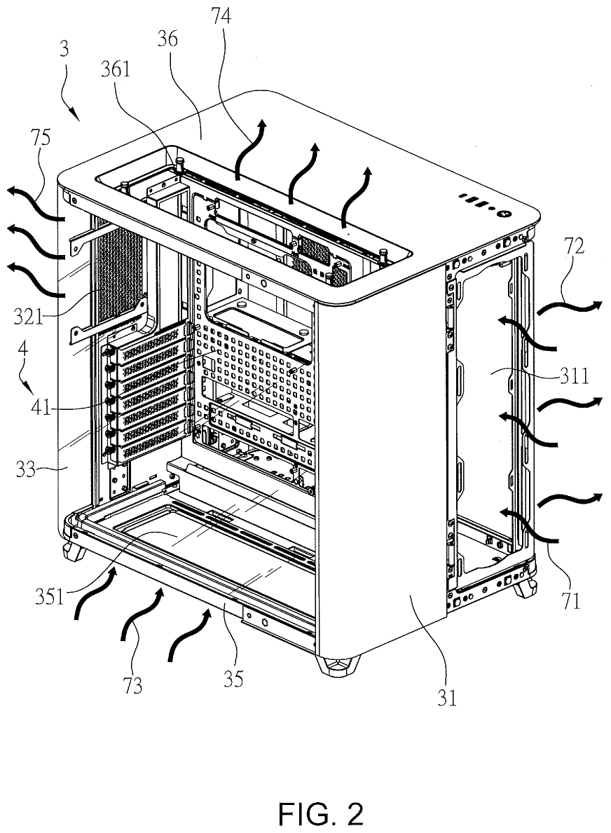

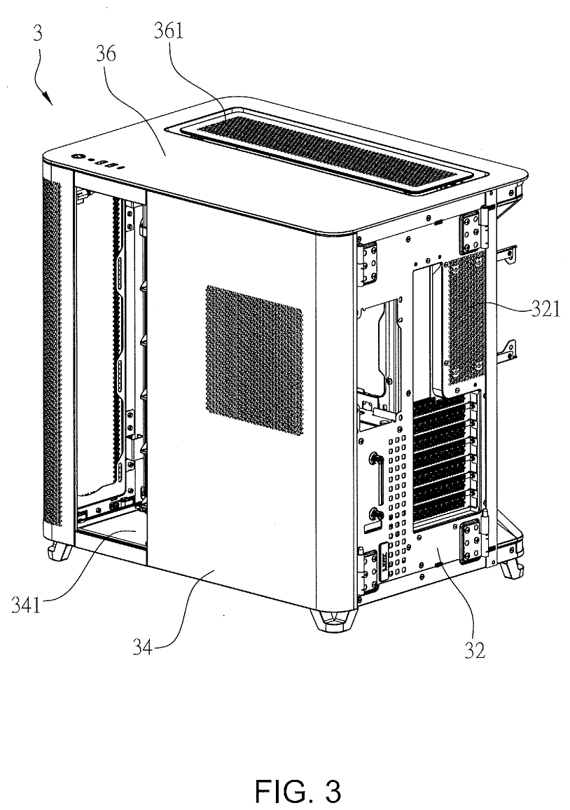

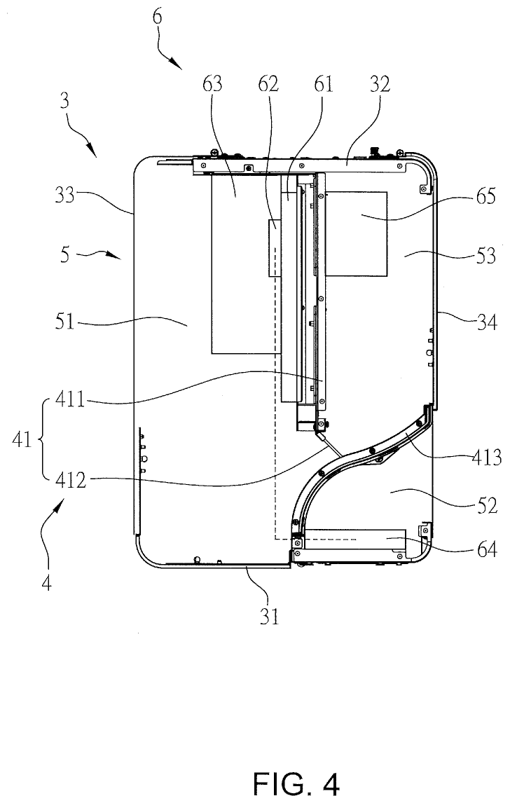

Referring to FIGS. 2, 3, and 4, a three-chamber chassis device according to a first embodiment of the present invention is illustrated. The three-chamber chassis device comprises a housing unit 3, a partition unit 4, and a chamber unit 5. The three-chamber chassis device is configured to accommodate a computer device 6.

The housing unit 3 comprises a front panel 31, a rear panel 32, a left panel 33, a right panel 34, a bottom structure 35, and a top structure 36. The front panel 31, the rear panel 32, the left panel 33, and the right panel 34 are sequentially connected and circumferentially arranged between the bottom structure 35 and the top structure 36. The housing unit 3 is generally rectangular in shape. In the some embodiments, the left panel 33 employs a transparent side panel, but the invention is not so limited.

The partition unit 4 comprises a partition structure 41 disposed within the housing unit 3. The transverse cross-sectional profile of the partition structure 41 is T-shaped. The partition structure 41 is connected to the front panel 31, the rear panel 32, and the right panel 34, respectively, extends longitudinally downward to the bottom structure 35, and extends longitudinally upward to the top structure 36.

The chamber unit 5 is disposed in the housing unit 3 and comprises a first chamber 51, a second chamber 52, and a third chamber 53, all separated by the partition structure 41. The first chamber 51 is defined by the partition structure 41, the front panel 31, the rear panel 32, the left panel 33, the bottom structure 35, and the top structure 36. The second chamber 52 is defined by the partition structure 41, the front panel 31, the right panel 34, the bottom structure 35, and the top structure 36. The third chamber 53 is defined by the partition structure 41, the rear panel 32, the right panel 34, the bottom structure 35, and the top structure 36.

In some embodiments, the partition structure 41 comprises a first plate member 411 connected to the rear panel 32, a second plate member 412 connected to the first plate member 411, and a third plate member 413 connected to the second plate member 412, the front panel 31, and the right panel 34. The third plate member 413 is arcuately contoured and curves toward the first plate member 411 between the right panel 34 and the front panel 31, resulting in a modified T-shaped configuration. The first chamber 51 is cooperatively defined by the front panel 31, the rear panel 32, the left panel 33, the first plate member 411, the second plate member 412, and the third plate member 413. The second chamber 52 is cooperatively defined by the front panel 31, the right panel 34, and the third plate member 413. The third chamber 53 is cooperatively defined by the front panel 31, the rear panel 32, the right panel 34, the first plate member 411, the second plate member 412, and the third plate member 413. In some embodiments, the partition structure 41 may alternatively be formed by providing a plate member between the front panel 31 and the rear panel 32 and providing another plate member between said plate member and the right panel 34, so that the partition structure 41 presents a T-shaped configuration. Since the partition structure 41 is amenable to various structural variations, further descriptions are omitted.

In some embodiments, the computer device 6 comprises a motherboard 61 disposed in the first chamber 51, a central processing unit (CPU) 62 mounted on the motherboard 61, a graphics processing unit (GPU) 63 mounted on the motherboard 61, a first heat sink 64 disposed in the second chamber 52, and a power supply unit 65 disposed in the third chamber 53.

The heat-generating components of the computer device 6 are the CPU 62, the GPU 63, and the power supply unit 65. In the present invention, a second heat sink (not shown) is mounted on the GPU 63 and is located in the first chamber 51, enabling heat from the GPU 63 to be released directly into the first chamber 51. The first heat sink 64 directs heat from the CPU 62 into the second chamber 52. Heat generated by the power supply unit 65 may be discharged directly to the exterior of the housing unit or into the third chamber 53. Since the heat generated by the GPU 63, the CPU 62, and the power supply unit 65 is directed into the first chamber 51, the second chamber 52, and the third chamber 53, respectively, each component has a dedicated independent chamber for heat dissipation and is therefore unaffected by heat generated by other computer components. In some embodiments, the power supply unit 65 is mounted on the rear panel 32, and a vent (not shown) is provided on the bottom structure 35. The third chamber 53 draws in air through the vent on the bottom structure 35; after this air flows into the power supply unit 65, it is discharged outward through the rear panel 32. In some embodiments, the power supply unit 65 also incorporates a fan to forcibly draw air from the third chamber 53 into the power supply unit 65 and then discharge it outward.

In some embodiments, the GPU 63 disposed in the first chamber 51 is connected to the first heat sink 64 to direct heat into the second chamber 52, while the second heat sink is mounted on the CPU 62 to direct heat into the first chamber 51. In some embodiments, the CPU 62 and the GPU 63 are both connected to the same first heat sink 64. In some embodiments, the computer device 6 further comprises a GPU 63 disposed in the second chamber 52 and a first heat sink 64 mounted on the GPU 63; in this configuration, the GPU 63 is connected to the motherboard 61 via a cable assembly (not shown), and the second heat sink is mounted on the CPU 62.

The front panel 31 has a first front ventilation portion 311 communicating with the second chamber 52, and the right panel 34 has a first right ventilation portion 341 communicating with the second chamber 52. In some embodiments, the first front ventilation portion 311 comprises a ventilation opening and a fan mounting bracket, and the first right ventilation portion 341 comprises a ventilation opening. The second chamber 52 draws in air through the first front ventilation portion 311 (as indicated by first airflow direction 71 in FIG. 2) and discharges air through the first right ventilation portion 341 (as indicated by second airflow direction 72 in FIG. 2).

The top structure 36 has a first top ventilation portion 361 communicating with the first chamber 51, the bottom structure 35 has a first bottom ventilation portion 351 communicating with the first chamber 51, and the rear panel 32 has a first rear ventilation portion 321 communicating with the first chamber 51. The first top ventilation portion 361 and the first bottom ventilation portion 351 are fan mounting brackets that can also accommodate liquid cooling radiators. The first rear ventilation portion 321 is a fan mounting bracket. The first chamber 51 draws in air through the first bottom ventilation portion 351 (as indicated by third airflow direction 73 in FIG. 2) and discharges air through both the first top ventilation portion 361 (as indicated by fourth airflow direction 74 in FIG. 2) and the first rear ventilation portion 321 (as indicated by fifth airflow direction 75 in FIG. 2).

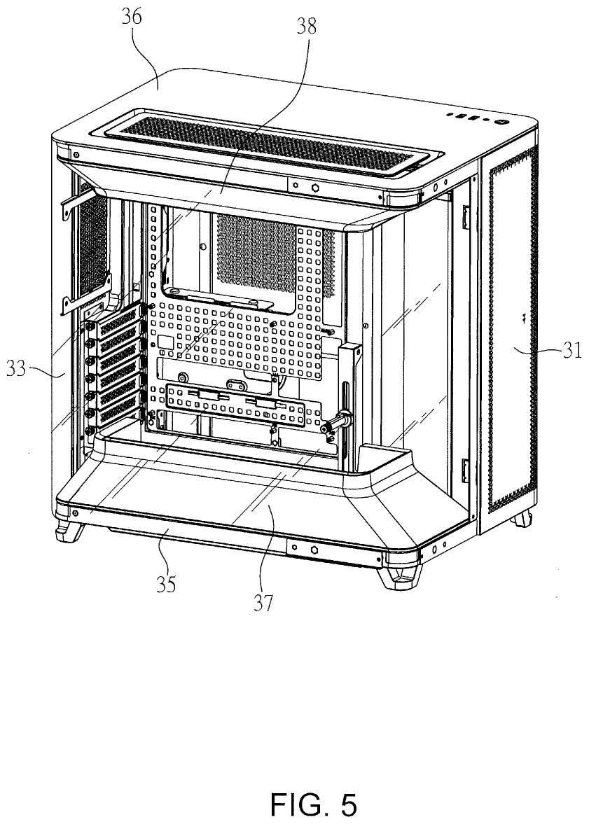

Referring to FIG. 5, a three-chamber chassis device according to a second embodiment of the present invention is illustrated. The second embodiment is substantially the same as the first embodiment and the similarities will not be reiterated. The difference resides in that the housing unit 3 of the second embodiment further comprises a bottom air guide 37 connected to the bottom structure 35 and a top air guide 38 connected to the top structure 36. The bottom air guide 37 communicates the first chamber 51 with the first bottom ventilation portion 351 and tapers in cross-sectional area from the first bottom ventilation portion 351 toward the first chamber 51. The top air guide 38 communicates the first chamber 51 with the first top ventilation portion 361 and tapers in cross-sectional area from the first top ventilation portion 361 toward the first chamber 51.

Because the GPU 63 is disposed in the first chamber 51 and generates substantial heat, the upper opening of the bottom air guide 37 is aligned with the location of the GPU 63, and the lower opening of the top air guide 38 is also aligned with the location of the GPU 63. This configuration enables rapid channeling of ambient-temperature air from outside to the vicinity of the GPU 63, while efficiently exhausting hot air from the first chamber 51 to the exterior.

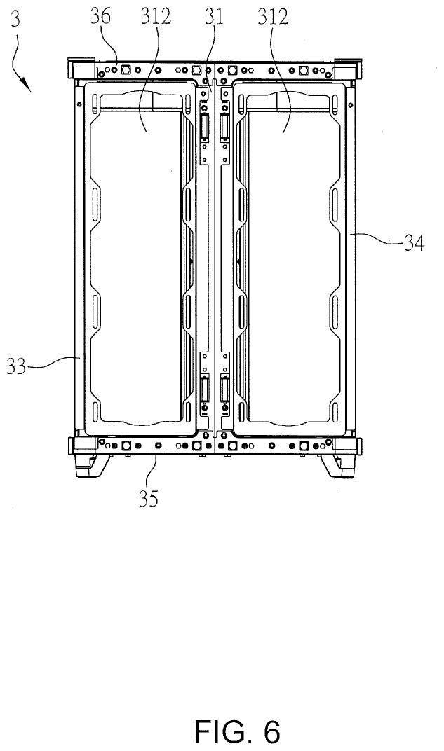

Referring to FIG. 6, a three-chamber chassis device according to a third embodiment of the present invention is illustrated. The third embodiment is substantially the same as the first embodiment and the similarities will not be reiterated. The difference resides in that the front panel 31 of the third embodiment is further provided with a second front ventilation portion 312 communicating with the first chamber 51.

Both the second front ventilation portion 312 and the first front ventilation portion 311 are fan mounting brackets capable of securing cooling fans. The first front ventilation portion 311 allows air to be directed from the front panel 31 into the second chamber 52, while the second front ventilation portion 312 allows air to be directed from the front panel 31 into the first chamber 51.

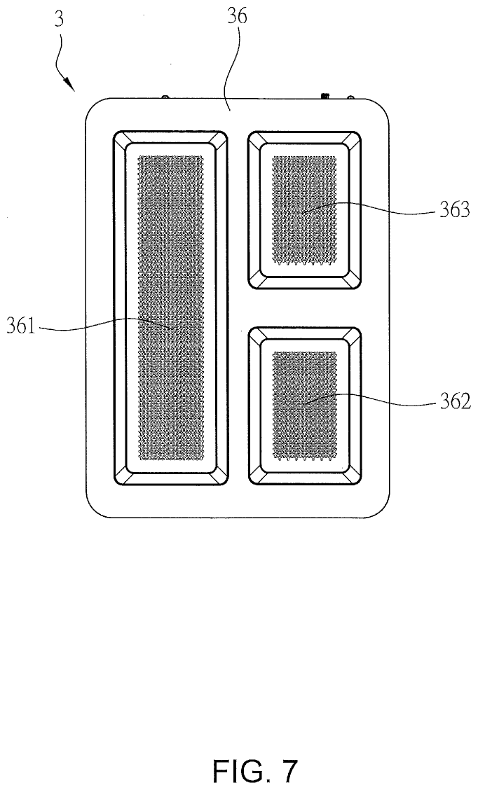

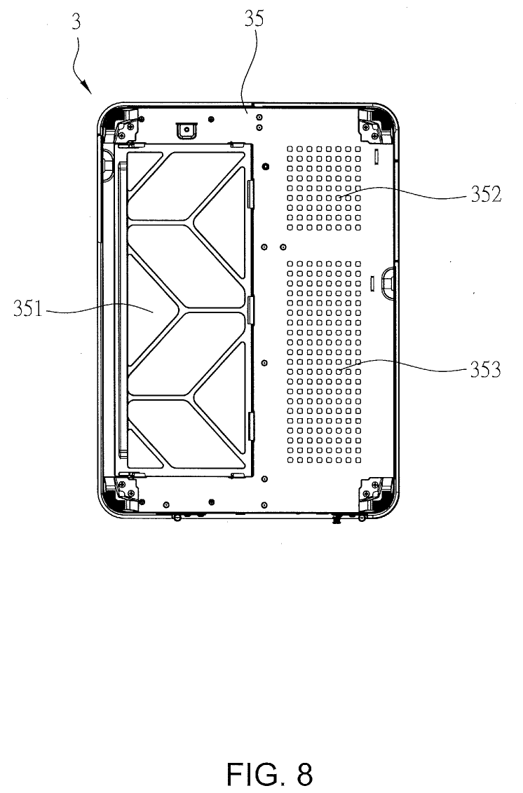

Referring to FIGS. 7 and 8, a three-chamber chassis device according to a fourth embodiment of the present invention is illustrated. The fourth embodiment is substantially the same as the first embodiment and the similarities will not be reiterated. The difference resides in that the top structure 36 of the fourth embodiment further comprises a second top ventilation portion 362 communicating with the second chamber 52 and a third top ventilation portion 363 communicating with the third chamber 53. The bottom structure 35 further comprises a second bottom ventilation portion 352 communicating with the second chamber 52 and a third bottom ventilation portion 353 communicating with the third chamber 53.

The first top ventilation portion 361, the second top ventilation portion 362, and the third top ventilation portion 363 are ventilation structures on the top structure 36. The first bottom ventilation portion 351, the second bottom ventilation portion 352, and the third bottom ventilation portion 353 are ventilation structures on the bottom structure 35. In some embodiments, fans may be installed in any of these ventilation portions.

The first bottom ventilation portion 351 is disposed at the bottom of the first chamber 51, and the first top ventilation portion 361 is disposed at the top of the first chamber 51. The first chamber 51 draws in air from the first bottom ventilation portion 351 and discharges air through the first top ventilation portion 361, thereby enabling the first chamber 51—defined by the partition structure 41, the front panel 31, the rear panel 32, the left panel 33, the first bottom ventilation portion 351 of the bottom structure 35, and the first top ventilation portion 361 of the top structure 36—to form an independent chimney-style heat dissipation structure.

In some embodiments, the front panel 31 need not be provided with the first front ventilation portion 311, and the right panel 34 need not be provided with the first right ventilation portion 341. The second bottom ventilation portion 352 is disposed at the bottom of the second chamber 52, and the second top ventilation portion 362 is disposed at the top of the second chamber 52. The second chamber 52 draws in air from the second bottom ventilation portion 352 and discharges air through the second top ventilation portion 362, thereby enabling the second chamber 52—defined by the partition structure 41, the front panel 31, the right panel 34, the second bottom ventilation portion 352 of the bottom structure 35, and the second top ventilation portion 362 of the top structure 36—to form an independent chimney-style heat dissipation structure.

The third bottom ventilation portion 353 is disposed at the bottom of the third chamber 53, and the third top ventilation portion 363 is disposed at the top of the third chamber 53. The third chamber 53 draws in air from the third bottom ventilation portion 353 and discharges air through the third top ventilation portion 363, thereby enabling the third chamber 53—defined by the partition structure 41, the rear panel 32, the right panel 34, the third bottom ventilation portion 353 of the bottom structure 35, and the third top ventilation portion 363 of the top structure 36-to form an independent chimney-style heat dissipation structure.

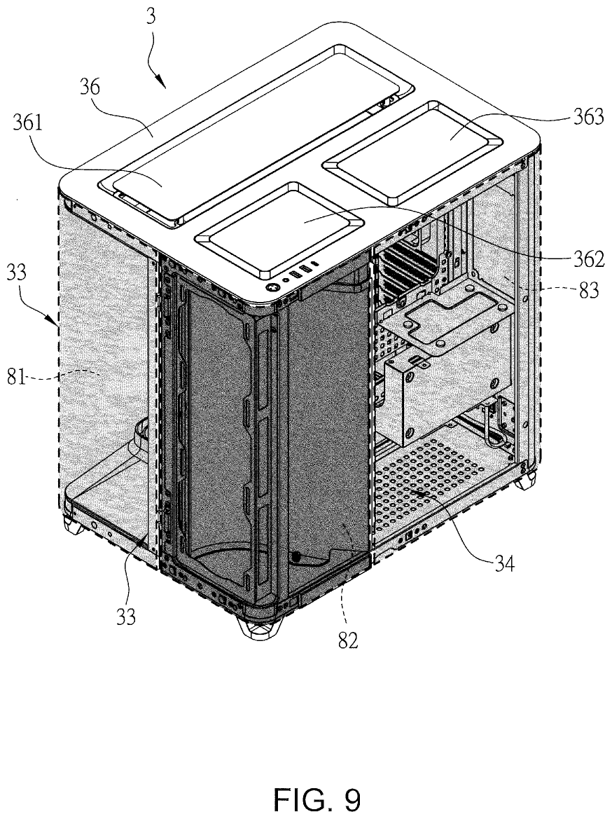

Referring to FIG. 9, since the first chamber 51, the second chamber 52, and the third chamber 53 have each independently formed chimney-style heat dissipation structures, the front panel 31, the left panel 33, and the right panel 34 may all employ transparent panels. In some embodiments, a first transparent side panel 81 is disposed on the left region of the front panel 31 and on the left panel 33; a second transparent side panel 82 is disposed on the right region of the front panel 31 and the left region of the right panel 34; and a third transparent side panel 83 is disposed on the right region of the right panel 34. Accordingly, the internal structure of the housing unit 3 is rendered visible to the outside through the first transparent side panel 81, the second transparent side panel 82, and the third transparent side panel 83.

From the foregoing description, the three-chamber chassis device of the present invention provides the following features:
(1) Chimney-style heat dissipation structures that enhance computer thermal management:

Chimney-style heat dissipation structures exploit the physical property of hot air rising, enabling heat to be exhausted from the chassis from bottom to top. This reduces heat accumulation and also supplements fan-based cooling, allowing fan speed to be reduced and thereby decreasing noise and power consumption. The first chamber 51, the second chamber 52, and the third chamber 53 can each receive air intake from the bottom and discharge air from the top, independently forming chimney-style heat dissipation structures. These structures not only provide excellent heat dissipation efficiency but also operate independently without mutual thermal interference, effectively promoting heat dissipation in personal computers or high-performance computing systems and maintaining efficient operation.
(2) Full-panel transparent side panels providing all-around visibility of internal components:

Since the first chamber 51, the second chamber 52, and the third chamber 53 each form independent chimney-style heat dissipation structures, the side panels do not require ventilation structures. The front panel 31, the left panel 33, and the right panel 34 may all employ transparent panels to display the computer device 6 and its components installed within the housing unit 3, providing users with an unobstructed all-around view of the internal components. This is consistent with the contemporary trend toward panoramic chassis designs.
(3) Effective control over the maximum structural height of the housing: Although the first chamber 51, the second chamber 52, and the third chamber 53 accommodate different computer components, all three chambers are disposed at the same height. The present invention does not give rise to a stacked-space configuration. Even when the motherboard 61, the GPU 63, and the power supply unit 65 are installed in an upright orientation, the structural height of the housing unit 3 need not be additionally increased, thereby enabling effective control over the maximum height of the chassis structure and expanding its range of applicable use environments.

In summary, the partition structure 41 extends longitudinally between the bottom structure 35 and the top structure 36 to render the first chamber 51, the second chamber 52, and the third chamber 53 mutually independent. Heat generated by the CPU 62, the GPU 63, and the power supply unit 65 does not interfere with one another. The three chambers are disposed at the same height, obviating the need to increase the structural height of the housing unit 3. Each of the three chambers independently forms a chimney-style heat dissipation structure, thereby improving heat dissipation efficiency and conserving energy. The front panel 31, the left panel 33, and the right panel 34 may employ transparent panels to display the computer device 6 installed within the housing unit 3 to the outside.

The foregoing outlines features of several embodiments so that those skilled in the art may better understand the aspects of the present invention. Those skilled in the art should appreciate that they may readily use the present invention as a basis for designing or modifying other processes and structures for carrying out the same purposes and/or achieving the same advantages of the embodiments introduced herein. Those skilled in the art should also realize that such equivalent constructions do not depart from the spirit and scope of the present invention, and that they may make various changes, substitutions, and alterations herein without departing from the scope of the present invention.

We claim:

1. A three-chamber chassis device, comprising:
a housing unit (3) comprising a front panel (31), a rear panel (32), a left panel (33), a right panel (34), a bottom structure (35), and a top structure (36), wherein the front panel (31), the rear panel (32), the left panel (33), and the right panel (34) are sequentially connected and arranged around the bottom structure (35) and the top structure (36);
a partition unit (4), comprising a partition structure (41) arranged within the housing unit (3), the partition structure (41) being connected to the front panel (31), the rear panel (32), and the right panel (34) respectively, and extending longitudinally to the bottom structure (35) and the top structure (36); and
a chamber unit (5) disposed in the housing unit (3) and comprising a first chamber (51), a second chamber (52), and a third chamber (53) separated by the partition structure (41), wherein the first chamber (51) is defined by the partition structure (41), the front panel (31), the rear panel (32), the left panel (33), the bottom structure (35), and the top structure (36); the second chamber (52) is defined by the partition structure (41), the front panel (31), the right panel (34), the bottom structure (35), and the top structure (36); and the third chamber (53) is defined by the partition structure (41), the rear panel (32), the right panel (34), the bottom structure (35), and the top structure (36).

2. The three-chamber chassis device as claimed in claim 1, wherein the three-chamber chassis device is configured to accommodate a computer device (6), the computer device (6) comprising a motherboard (61) disposed in the first chamber (51), a central processing unit (62) mounted on the motherboard (61), and a power supply unit (65) disposed in the third chamber (53), air entering the third chamber (53) from the bottom structure (35) and being discharged outward through the power supply unit (65).

3. The three-chamber chassis device as claimed in claim 2, wherein the computer device (6) further comprises a graphics processing unit (63) mounted on the motherboard (61), and a heat sink disposed in the second chamber (52), the heat sink being connected to the central processing unit (62) and/or the graphics processing unit (63).

4. The three-chamber chassis device as claimed in claim 2, wherein the computer device (6) further comprises a graphics processing unit (63) disposed in the second chamber (52), and a heat sink mounted on the graphics processing unit (63).

5. The three-chamber chassis device as claimed in claim 1, wherein the partition structure (41) comprises a first plate member (411) connected to the rear panel (32), a second plate member (412) connected to the first plate member

(411) and a third plate member (413) connected to the second plate member (412), the front panel (31), and the right panel (34), wherein the second chamber (52) is cooperatively defined by the front panel (31), the right panel (34), and the third plate member (413).

6. The three-chamber chassis device as claimed in claim 1, wherein the front panel (31) has a first front ventilation portion (311) communicating with the second chamber (52), and the right panel (34) has a first right ventilation portion (341) communicating with the second chamber (52), air entering the second chamber (52) through the first front ventilation portion (311) and being discharged outward through the first right ventilation portion (341).

7. The three-chamber chassis device as claimed in claim 1, wherein the top structure (36) has a first top ventilation portion (361) communicating with the first chamber (51), the bottom structure (35) has a first bottom ventilation portion (351) communicating with the first chamber (51), and the rear panel (32) has a first rear ventilation portion (321) communicating with the first chamber (51), air entering the first chamber (51) through the first bottom ventilation portion (351) and being discharged outward through the first top ventilation portion (361) and the first rear ventilation portion (321).

8. The three-chamber chassis device as claimed in claim 7, wherein the housing unit (3) further comprises a bottom air guide (37) connected to the bottom structure (35) and a top air guide (38) connected to the top structure (36), the bottom air guide (37) communicating the first chamber (51) with the first bottom ventilation portion (351) and tapering from the first bottom ventilation portion (351) toward the first chamber (51), the top air guide (38) communicating the first chamber (51) with the first top ventilation portion (361) and tapering from the first top ventilation portion (361) toward the first chamber (51).

9. The three-chamber chassis device as claimed in claim 1, wherein the front panel (31) has a second front ventilation portion (312) communicating with the first chamber (51).

10. The three-chamber chassis device as claimed in claim 1, wherein the bottom structure (35) has a first bottom ventilation portion (351) communicating with the first chamber (51), a second bottom ventilation portion (352) communicating with the second chamber (52), and a third bottom ventilation portion (353) communicating with the third chamber (53); and the top structure (36) has a first top ventilation portion (361) communicating with the first chamber (51), a second top ventilation portion (362) communicating with the second chamber (52), and a third top ventilation portion (363) communicating with the third chamber (53); wherein air enters the first chamber (51) through the first bottom ventilation portion (351) and is discharged outward through the first top ventilation portion (361), air enters the second chamber (52) through the second bottom ventilation portion (352) and is discharged outward through the second top ventilation portion (362), and air enters the third chamber (53) through the third bottom ventilation portion (353) and is discharged outward through the third top ventilation portion (363).
